(19) United States
(12) Patent Application Publication
(10) Pub. No.: US 2016/0064392 A1
(43) Pub. Date: Mar. 3, 2016

(54) SEMICONDUCTOR MEMORY DEVICE

(71) Applicant: Kabushiki Kaisha Toshiba, Minato-ku (JP)

(72) Inventors: Ken KOMIYA, Yokkaichi (JP); Noriaki MIKASA, Kuwana (JP)

(73) Assignee: Kabushiki Kaisha Toshiba, Minato-ku (JP)

(21) Appl. No.: 14/628,701

(22) Filed: Feb. 23, 2015

Related U.S. Application Data
(60) Provisional application No. 62/042,325, filed on Aug. 27, 2014.

(51) Int. Cl. H01L 27/115; H01L 29/788

(52) U.S. Cl. CPC H01L 27/11519; H01L 29/788; H01L 27/11521

(57) ABSTRACT

According to an embodiment, a semiconductor memory device comprises: a semiconductor layer; a first gate insulating film; a floating gate electrode; a second gate insulating film; and a control gate electrode. The semiconductor layer is provided on a substrate and extends in a certain direction. The first gate insulating film is formed on the semiconductor layer. The floating gate electrode is formed along the semiconductor layer on the first gate insulating film. The second gate insulating film is formed on an upper surface of the floating gate electrode. The control gate electrode faces the upper surface of the floating gate electrode via the second gate insulating film. The control gate electrode comprises: a first portion intersecting the certain direction at a first angle; and a second portion intersecting the certain direction at a second angle different from the first angle.

### CROSS-REFERENCE TO RELATED APPLICATIONS

This application is based upon and claims the benefit of U.S. Provisional Patent Application No. 62/042,325, filed on Aug. 27, 2014, the entire contents of which are incorporated herein by reference.

### BACKGROUND

1. Field

Embodiments described here relate to a semiconductor memory device.

2. Description of the Related Art

A memory cell configuring a semiconductor memory device such as a NAND type flash memory includes a semiconductor layer, a control gate electrode, and a charge accumulation layer. The memory cell changes its threshold voltage according to a charge accumulated in the charge accumulation layer to store a magnitude of this threshold voltage as data. In recent years, enlargement of capacity and raising of integration level has been proceeding in such a semiconductor memory device.

### BRIEF DESCRIPTION OF THE DRAWINGS

FIG. 1 is a block diagram showing a schematic configuration of a nonvolatile semiconductor memory device according to a first embodiment.

FIG. 2 is a circuit diagram showing a configuration of part of the same nonvolatile semiconductor memory device.

FIG. 3A is a schematic cross-sectional view showing a configuration of part of the same nonvolatile semiconductor memory device.

FIG. 3B is a schematic cross-sectional view showing a configuration of part of the same nonvolatile semiconductor memory device.

FIG. 4 is a schematic plan view showing a configuration of part of the same nonvolatile semiconductor memory device.

FIG. 5 is a cross-sectional view showing a manufacturing process of the same nonvolatile semiconductor memory device.

FIG. 6 is a cross-sectional view showing a manufacturing process of the same nonvolatile semiconductor memory device.

FIG. 7 is a cross-sectional view showing a manufacturing process of the same nonvolatile semiconductor memory device.

FIG. 8 is a cross-sectional view showing a manufacturing process of the same nonvolatile semiconductor memory device.

FIG. 9 is a cross-sectional view showing a manufacturing process of the same nonvolatile semiconductor memory device.

FIG. 10 is a cross-sectional view showing a manufacturing process of the same nonvolatile semiconductor memory device.

FIG. 11 is a cross-sectional view showing a manufacturing process of the same nonvolatile semiconductor memory device.

FIG. 12 is a cross-sectional view showing a manufacturing process of the same nonvolatile semiconductor memory device.

FIG. 13A is a cross-sectional view showing a manufacturing process of the same nonvolatile semiconductor memory device.

FIG. 13B is a cross-sectional view showing a manufacturing process of the same nonvolatile semiconductor memory device.

FIG. 13C is a plan view showing a manufacturing process of the same nonvolatile semiconductor memory device.

FIG. 14 is a cross-sectional view showing a manufacturing process of the same nonvolatile semiconductor memory device.

FIG. 15A is a cross-sectional view showing a manufacturing process of the same nonvolatile semiconductor memory device.

FIG. 15B is a plan view showing a manufacturing process of the same nonvolatile semiconductor memory device.

FIG. 16 is a cross-sectional view showing a manufacturing process of the same nonvolatile semiconductor memory device.

FIG. 17A is a cross-sectional view showing a manufacturing process of the same nonvolatile semiconductor memory device.

FIG. 17B is a plan view showing a manufacturing process of the same nonvolatile semiconductor memory device.

FIG. 18 is a cross-sectional view showing a manufacturing process of the same nonvolatile semiconductor memory device.

FIG. 19 is a schematic plan view showing a configuration of part of a nonvolatile semiconductor memory device according to a second embodiment.

FIG. 20 is a schematic plan view showing a configuration of part of a nonvolatile semiconductor memory device according to a third embodiment.

FIG. 21 is a schematic plan view showing a configuration of part of the same nonvolatile semiconductor memory device.

FIG. 22 is a schematic plan view showing a configuration of part of a nonvolatile semiconductor memory device according to a fourth embodiment.

FIG. 23 is a schematic plan view showing a configuration of part of a nonvolatile semiconductor memory device according to a fifth embodiment.

FIG. 24 is a schematic plan view showing a configuration of part of a nonvolatile semiconductor memory device according to a sixth embodiment.

FIG. 25 is a schematic plan view showing a configuration of part of a nonvolatile semiconductor memory device according to a seventh embodiment.

FIG. 26 is a schematic plan view showing a configuration of part of a nonvolatile semiconductor memory device according to an eighth embodiment.

FIG. 27 is a circuit diagram showing an example of configuration of part of a nonvolatile semiconductor memory device according to another embodiment.

### DETAILED DESCRIPTION

A semiconductor memory device according to an embodiment described below comprises: a semiconductor layer; a first gate insulating film; a floating gate electrode; a second gate insulating film; and a control gate electrode. The semiconductor layer is provided on a substrate and extends in a certain direction. The first gate insulating film is formed on the semiconductor layer. The floating gate electrode is formed along the semiconductor layer on the first gate insulating film. The second gate insulating film is formed on an upper surface of the floating gate electrode. The control gate electrode faces the upper surface of the floating gate electrode via the second gate insulating film. The control gate electrode comprises: a first portion intersecting the certain direction at a first angle; and a second portion intersecting the certain direction at a second angle different from the first angle.

### First Embodiment

[Overall Configuration]

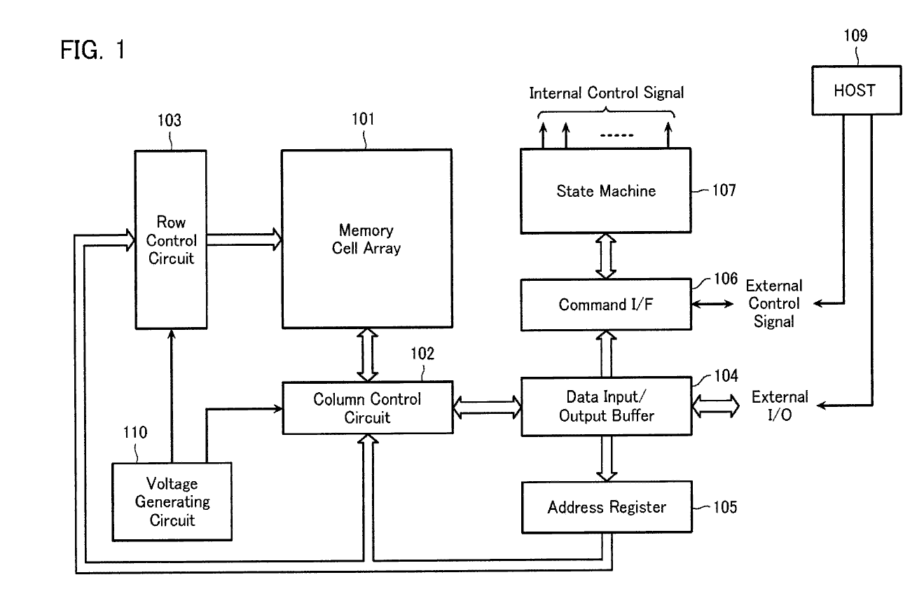

FIG. 1 is a block diagram of a nonvolatile semiconductor memory device according to a first embodiment. This nonvolatile semiconductor memory device includes a memory cell array 101 having a plurality of memory cells MC disposed substantially in a matrix therein, and comprising a bit line BL and a word line WL disposed orthogonally to each other and connected to these memory cells MC. Provided in a periphery of this memory cell array 101 are a column control circuit 102 and a row control circuit 103. The column control circuit 102 controls the bit line BL and performs data erase of the memory cell, data write to the memory cell, and data read from the memory cell. The row control circuit 103 selects the word line WL and applies a voltage for data erase of the memory cell, data write to the memory cell, and data read from the memory cell.

A data input/output buffer 104 is connected to an external host 109, via an I/O line, and receives write data, receives an erase command, outputs read data, and receives address data or command data. The data input/output buffer 104 sends received write data to the column control circuit 102, and receives data read from the column control circuit 102 to be outputted to external. An address supplied to the data input/output buffer 104 from external is sent to the column control circuit 102 and the row control circuit 103 via an address register 105.

Moreover, a command supplied to the data input/output buffer 104 from the host 109 is sent to a command interface 106. The command interface 106 receives an external control signal from the host 109, determines whether data inputted to the data input/output buffer 104 is write data or a command or an address, and, if a command, receives the data and transfers the data to a state machine 107 as a command signal.

The state machine 107 performs management of this nonvolatile memory overall, receives a command from the host 109, via the command interface 106, and performs management of read, write, erase, input/output of data, and so on.

In addition, it is also possible for the external host 109 to receive status information managed by the state machine 107 and judge an operation result. Moreover, this status information is utilized also in control of write and erase.

Furthermore, the state machine 107 controls a voltage generating circuit 110. This control enables the voltage generating circuit 110 to output a pulse of any voltage and any timing.

Now, the pulse formed by the voltage generating circuit 110 can be transferred to any line selected by the column control circuit 102 and the row control circuit 103. These column control circuit 102, row control circuit 103, state machine 107, voltage generating circuit 110, and so on, configure a control circuit in the present embodiment.

[Configuration of Memory Cell Array 101]

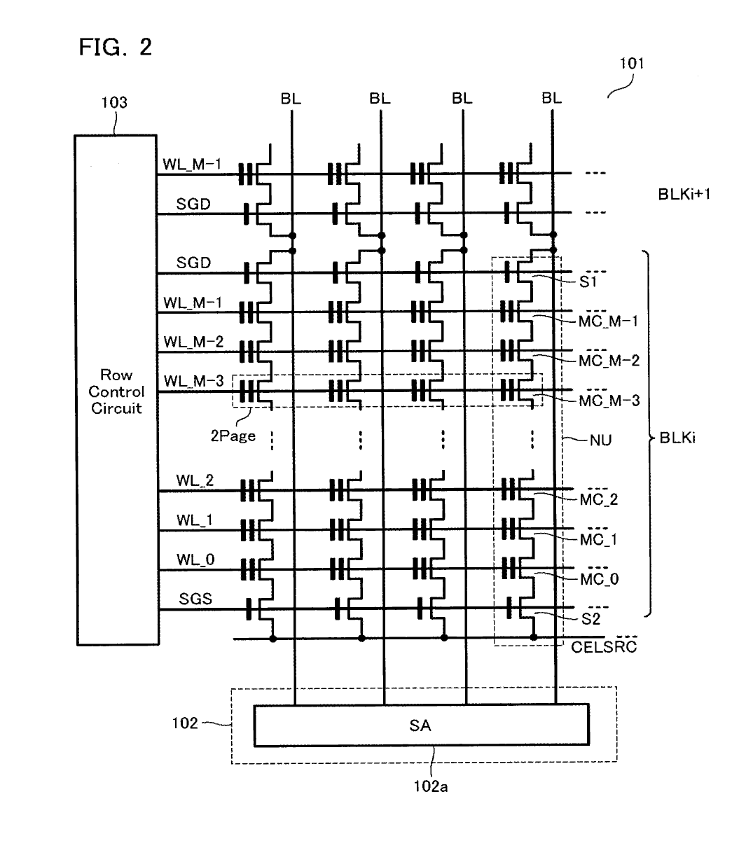

FIG. 2 is a circuit diagram showing a configuration of the memory cell array 101. As shown in FIG. 2, the memory cell array 101 is configured having NAND cell units NU arranged therein, each of the NAND cell units NU being configured having select gate transistors S1 and S2 respectively connected to both ends of a NAND string, the NAND string having M electrically rewritable nonvolatile memory cells MC_0 to MC_M−1 connected in series therein, sharing a source and a drain.

The NAND cell unit NU has one end (a select gate transistor S1 side) connected to the bit line BL and the other end (a select gate transistor S2 side) connected to a common source line CELSRC. Gate electrodes of the select gate transistors S1 and S2 are connected to select gate lines SGD and SGS. In addition, control gate electrodes of the memory cells MC_0 to MC_M−1 are respectively connected to word lines WL_0 to WL_M−1. The bit line BL is connected to a sense amplifier 102a of the column control circuit 102, and the word lines WL_0 to WL_M−1 and select gate lines SGD and SGS are connected to the row control circuit 103.

In the case of 2 bits/cell where 2 bits of data are stored in one memory cell MC, data stored in the plurality of memory cells MC connected to one word line WL configures 2 pages (an upper page UPPER and a lower page LOWER) of data.

One block BLK is formed by the plurality of NAND cell units NU sharing the word line WL. One block BLK forms a single unit of a data erase operation. The number of word lines WL in one block BLK in one memory cell array 101 is M, and, in the case of 2 bits/cell, the number of pages in one block is M×2 pages.

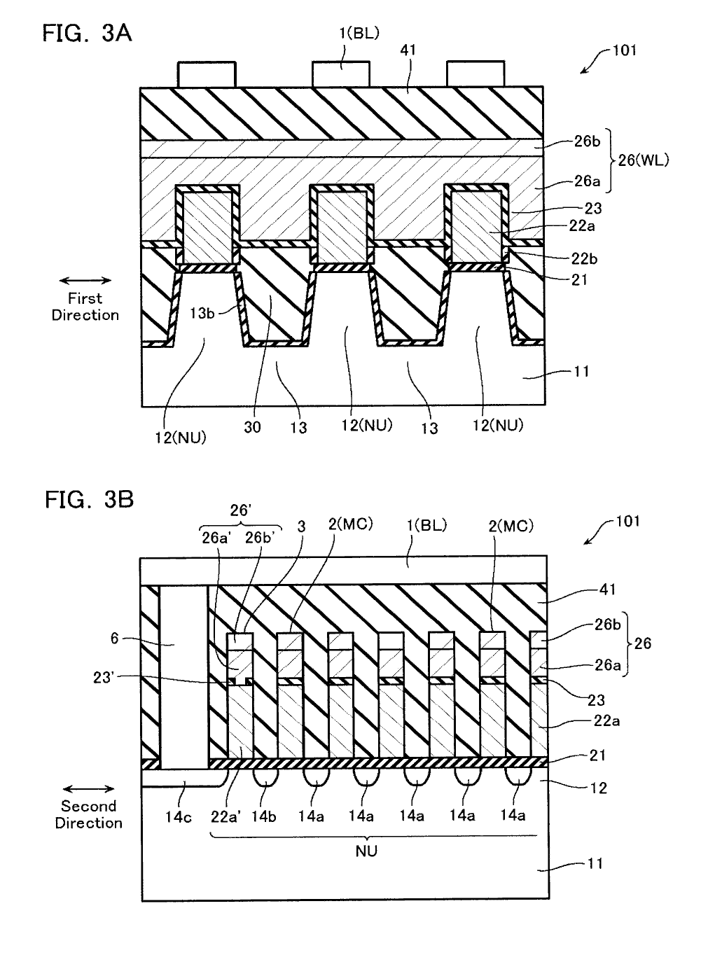

FIGS. 3A and 3B are schematic cross-sectional views each showing a configuration of part of the memory cell array 101. FIG. 3A shows schematically a cross-section where the memory cell array 101 is cut along the word line WL. In addition, FIG. 3B shows schematically a cross-section where the memory cell array 101 is cut along the NAND cell unit NU.

As shown in FIG. 3B, the memory cell array 101 is formed on a silicon substrate 11 and includes a plurality of memory cells 2 (MC) and a select transistor 3 that form the NAND cell unit NU. The plurality of memory cells 2 are arranged with a certain spacing along a semiconductor layer 12, and a source-drain diffusion layer 14a is shared by fellow adjacent memory cells 2. Similarly, the memory cell 2 and the select transistor 3 adjacent in a second direction share a source-drain diffusion layer 14b.

In addition, as shown in FIG. 3B, a bit line 1 (BL) extending in the second direction is formed on an upper portion of this NAND cell unit NU, and is connected to the NAND cell unit NU via a bit line contact 6 extending in a stacking direction. Moreover, two select transistors 3 are formed on both sides of the bit line contact 6 in the second direction thereof (one is not illustrated), and these two select transistors 3 and the bit line contact 6 share a source-drain diffusion layer 14c.

In addition, as shown in FIG. 3A, a plurality of such NAND cell units NU and bit lines BL are formed with a certain spacing in the first direction. An element isolation trench 13 is formed in a portion between the semiconductor layers 12 where the NAND cell units NU are formed, of the silicon substrate 11, and an insulating film 13b and an insulating film 22b are respectively formed on an inner wall of the element isolation trench 13 and on a lower portion side surface of a later-to-be-described floating gate electrode 22a. Moreover, an element isolation insulating film 30 is formed inside the element isolation trench 13. Furthermore, an inter-layer insulating film 41 is filled in between each of configurations.

As shown in FIG. 3B, each of the memory cells 2 (MC) is configured having stacked sequentially therein: the semiconductor layer 12; a first gate insulating film 21 (lower gate insulating film) which is a tunnel insulating film; the floating gate electrode 22a; a second gate insulating film 23 (upper gate insulating film); and a control gate electrode 26.

As shown in FIG. 3A, the control gate electrode 26 is continuously pattern formed straddling a plurality of the semiconductor layers 12 in a first direction, and configures the word line WL. Moreover, the control gate electrode 26 faces an upper surface and side surfaces of the floating gate electrode 22a via the second gate insulating film 23 (upper gate insulating film).

The control gate electrode 26 has a two-layer structure of a polycrystalline silicon film 26a and a tungsten silicide (WSi) film 26b. Materials of the films 26a and 26b are not limited to polycrystalline silicon or tungsten silicide, and, for example, a silicide film of polysilicon, and so on, may also be utilized. Moreover, it is also possible for the tungsten silicide film 26b to be omitted.

In addition, as shown in FIG. 3B, the select transistor 3 comprises: the semiconductor layer 12; the first gate insulating film 21; a gate electrode 22a′; an insulating film 23′; and a select gate line 26′ (films 26a′ and 26b′). The gate electrode 22a′, the insulating film 23′, and the films 26a′ and 26b′ are respectively formed by films of identical materials to those of each of portions 22a, 23, and 26a and 26b of the memory cell 2. Moreover, due to the second gate insulating film 23′ being partially removed, the select gate line 26′ is directly connected to (short-circuited with) the gate electrode 22a′.

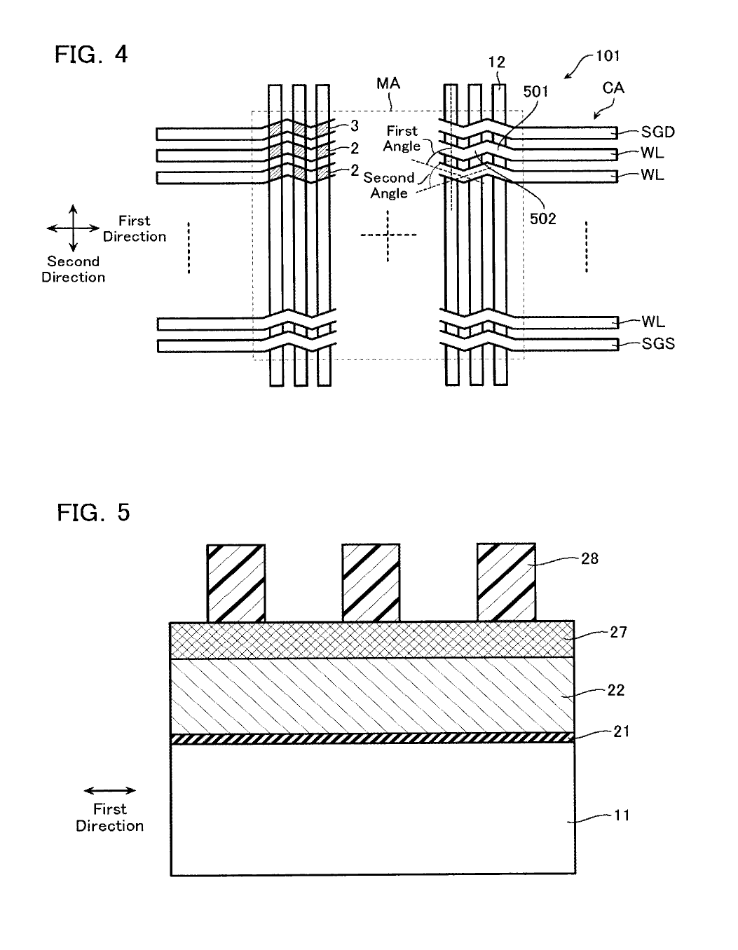

Next, a planar shape of the memory cell array 101 according to the present embodiment will be described with reference to FIG. 4. FIG. 4 is a schematic plan view of the memory cell array 101 according to the present embodiment. However, for convenience of explanation, FIG. 4 shows shapes of the semiconductor layer 12 and the word line WL.

As shown in FIG. 4, in the present embodiment, a plurality of the semiconductor layers 12 are arranged in the first direction and extend substantially linearly in the second direction intersecting the first direction. Moreover, in the present embodiment, a plurality of the word lines WL and the select gate lines SGD and SGS are arranged in the second direction and extend in the first direction. Furthermore, the word lines WL and the select gate lines SGD and SGS according to the present embodiment comprise: a first portion 501 intersecting the second direction at a first angle; and a second portion 502 intersecting the second direction at a second angle different from the first angle.

Now, although it will be described in detail later, a nonvolatile semiconductor memory device having such a configuration makes it possible to suppress collapse in a dividing direction of the word lines WL and the select gate lines SGD and SGS in a manufacturing process, makes it possible to achieve miniaturization and raising of integration level of the word lines WL and the select gate lines SGD and SGS, and makes it possible for the nonvolatile semiconductor memory device to be stably manufactured.

Note that the word lines WL and the select gate lines SGD and SGS can be formed in a variety of shapes comprising the first portion 501 and the second portion 502, but in the example shown in FIG. 4 are formed in a zigzag shape configured having the first portion 501 and the second portion 502 disposed repeatedly along the first direction. Moreover, in the present embodiment, in a memory area MA where the semiconductor layers 12 intersect the word lines WL and the select gate lines SGD and SGS, the word lines WL and the select gate lines SGD and SGS are formed in zigzags. On the other hand, in a lead-out wiring line area CA positioned outside of the memory area MA, the word lines WL and the select gate lines SGD and SGS extend substantially linearly in the first direction.

Moreover, in the example shown in FIG. 4, the word lines WL and the select gate lines SGD and SGS are formed in zigzags with a period which is twice a period with which the semiconductor layers 12 are arranged. In addition, the word lines WL and the select gate lines SGD and SGS intersect the semiconductor layers 12 at close to a center of the first portion 501 or the second portion 502, of the zigzag shape, and the memory cell 2 and the select transistor 3 are formed at this intersection. Furthermore, in the present embodiment, all of the word lines WL and the select gate lines SGD and SGS included in the memory cell array 101 are formed in zigzags in the memory area MA.

[Method of Manufacturing]

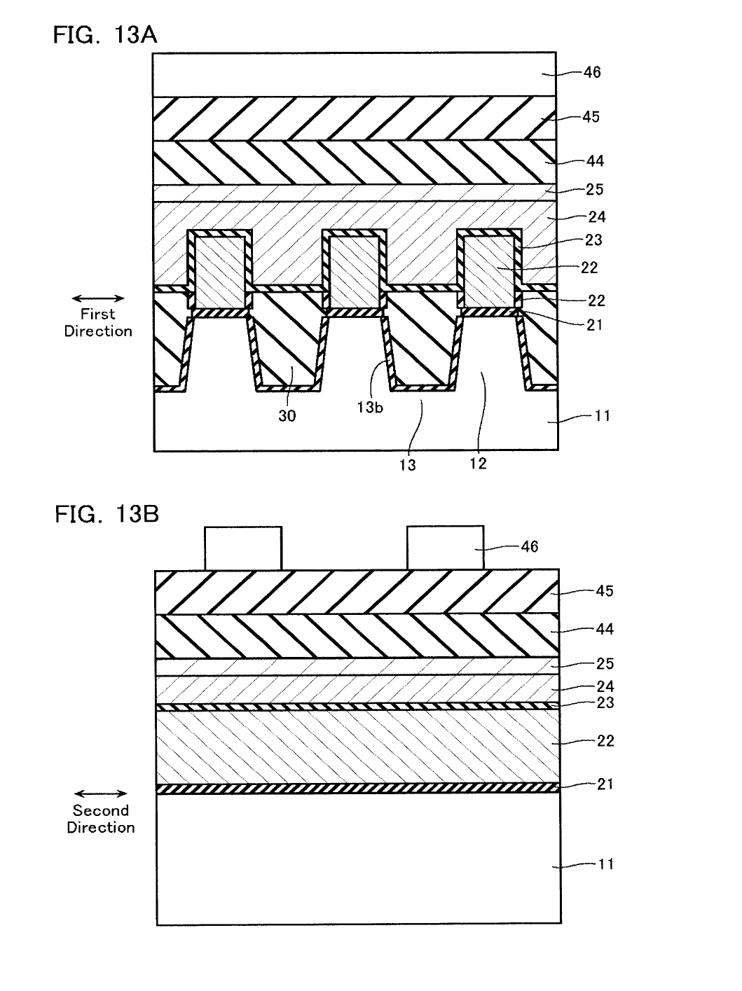

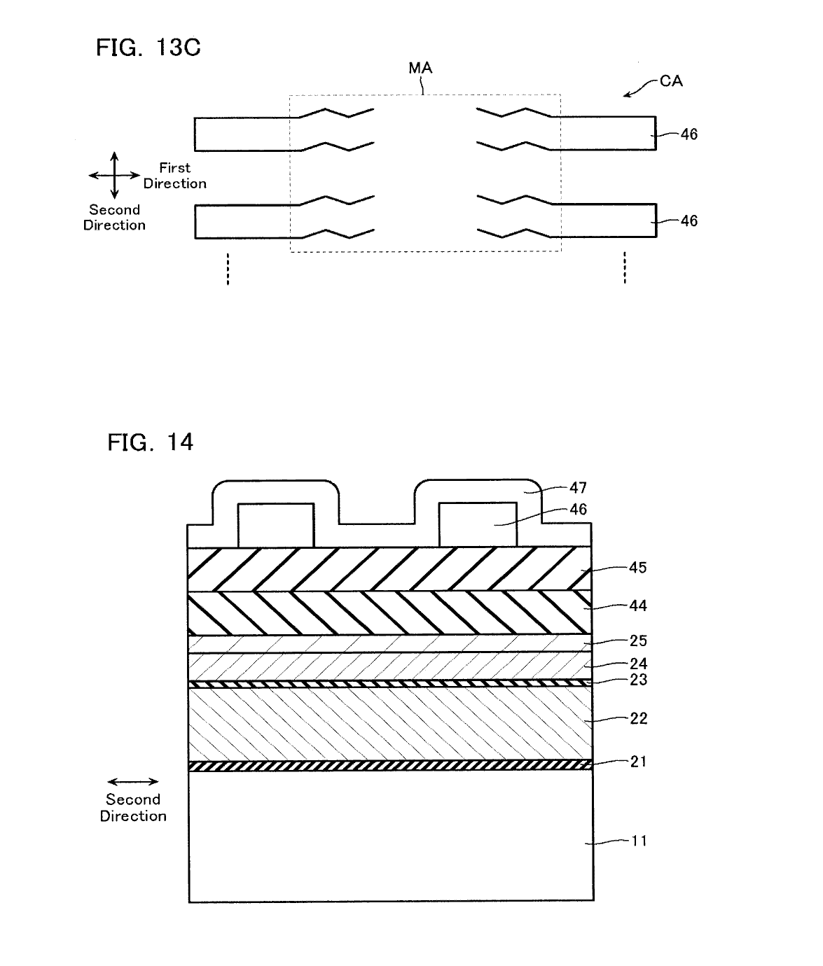

Next, a specific manufacturing process of a NAND type flash memory according to this embodiment will be described with reference to FIGS. 5 to 18. FIGS. 5 to 18 are cross-sectional views each showing a manufacturing process of the nonvolatile semiconductor memory device according to the present embodiment. FIGS. 5 to 12 and 13A show cross-sections corresponding to FIG. 3A; FIGS. 13B, 14, 15A, 16, 17A, and 18 show cross-sections corresponding to FIG. 3B; and FIGS. 13C, 15B, and 17B show plan views.

First, as shown in FIG. 5, a silicon oxide film is formed on the silicon substrate 11 as the first gate insulating film 21, a polysilicon film 22 is deposited on this silicon oxide film as a material film of the floating gate electrode 22a, and furthermore, a silicon nitride film 27 is formed as a stopper film in a CMP (chemical mechanical polishing) process. In addition, a resist pattern 28 is formed on the silicon nitride film 27.

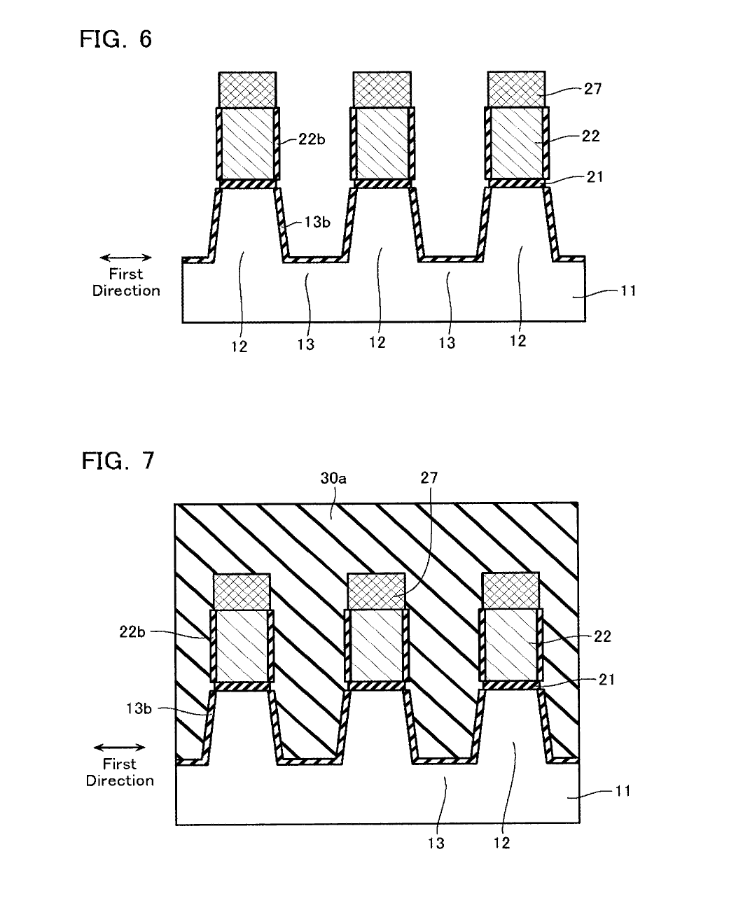

Next, as shown in FIG. 6, the silicon nitride film 27, the polysilicon film 22, the first gate insulating film 21, and an upper portion of the silicon substrate 11 are etched using the resist pattern 28 as an etching mask. As a result, the semiconductor layer 12 where the memory cell 2 is formed, and the element isolation trench 13 that partitions this, are formed. Moreover, in this process, the silicon nitride film 27, the polysilicon film 22, and the first gate insulating film 21 are divided in the first direction. Now, in the present process, patterning is performed using an identical resist pattern 28 as the mask, hence side surfaces of the polysilicon film 22, the first gate insulating film 21, and the semiconductor layer 12 are aligned with each other. After this, in order to remove damage due to etching, the silicon oxide film 22b is formed on side surfaces of the polysilicon film 22 and the silicon oxide film 13b is formed on side surfaces and a bottom surface of the element isolation trench 13, by a thermal oxidation method.

Next, as shown in FIG. 7, a silicon oxide film is formed and adopted as an element isolation insulating film formation layer 30a that forms the element isolation insulating film 30. The element isolation insulating film formation layer 30a is deposited on an entire surface including not only in the element isolation trench 13, but also on the silicon nitride film 27 formed on the semiconductor layer 12.

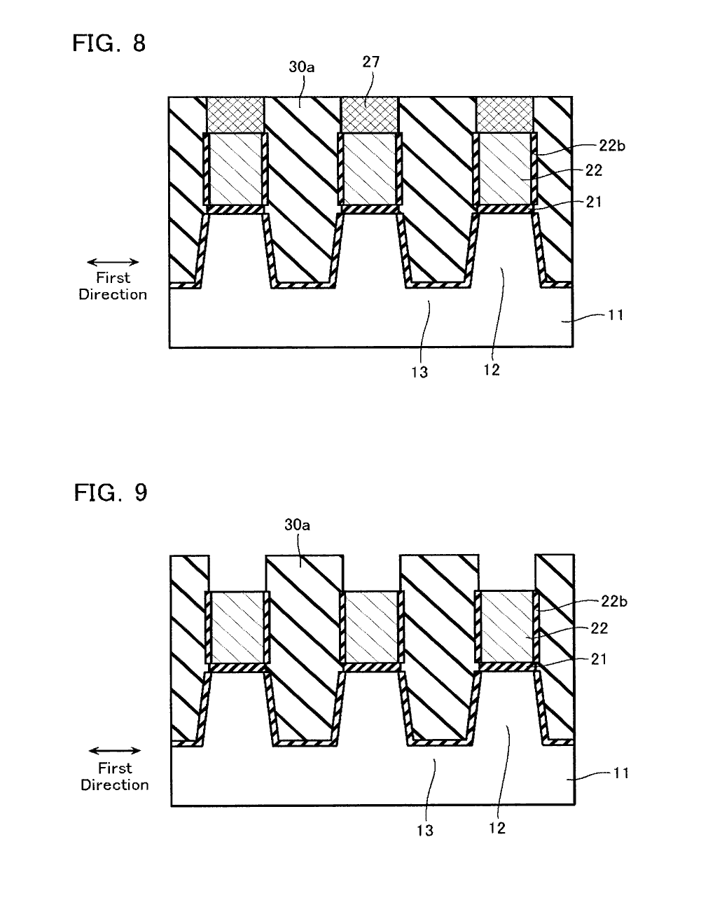

Next, as shown in FIG. 8, the element isolation insulating film formation layer 30a is removed/planarized to an upper surface of the silicon nitride film 27 by a CMP method using the silicon nitride film 27 as a stopper film.

Then, as shown in FIG. 9, the silicon nitride film 27 is removed by phosphating, and an upper surface of the polysilicon film 22 is exposed.

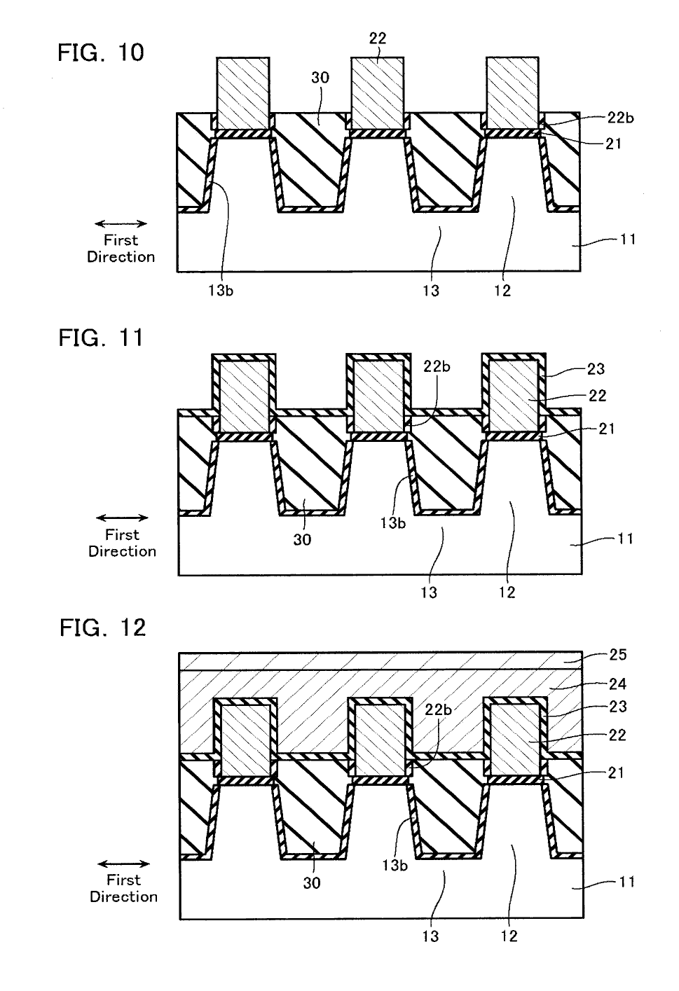

Then, as shown in FIG. 10, part of the element isolation insulating film formation layer 30a and part of the silicon oxide film 22b are removed by etching employing hydrofluoric acid to form the element isolation insulating film 30.

Next, as shown in FIG. 11, an ONO film of a certain thickness is formed on the upper surface and side surfaces of the polysilicon film 22 and on the element isolation insulating film 30, by a reduced pressure CVD method, as the second gate insulating film 23. The ONO film is an insulating film of a three-layer structure having formed stacked sequentially therein a first silicon oxide film, a silicon nitride film, and a second silicon oxide film. Note that in a region where the select transistor 3 is formed, the second gate insulating film 23 is partially removed to configure such that the polysilicon film 22 and the control gate electrode 26 are short-circuited.

Following this, as shown in FIG. 12, a polycrystalline silicon film 24 and a tungsten silicide film 25 are formed sequentially on this second gate insulating film 23, as materials of the control gate electrode 26.

Next, as shown in FIGS. 13A, 13B, and 13C, a first mask layer 44 and a second mask layer 45 are formed on the tungsten silicide film 25, and furthermore, a third mask layer 46 is formed on this second mask layer 45. As shown in FIG. 13C, the third mask layers 46 are arranged in the second direction, are a pattern extending in the first direction, are formed in zigzags in the memory area MA, and in the lead-out wiring line area CA, are formed substantially linearly and extend in the first direction. The third mask layer 46 is formed by, for example, photolithography and etching.

Next, as shown in FIG. 14, a first sacrifice film 47 is formed on an upper surface and side surfaces of the third mask layer 46 and on an upper surface of the second mask layer 45.

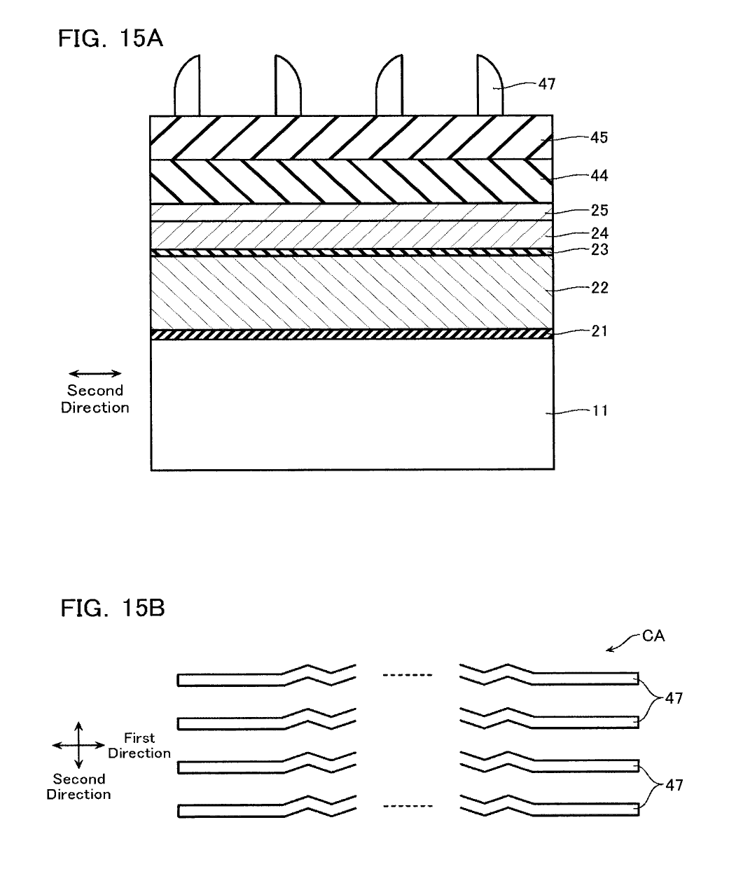

Next, as shown in FIG. 15A, the first sacrifice film 47 is removed leaving a portion formed on the side surfaces of the third mask layer 46, and then, the third mask layer 46 is removed. As a result, as shown in FIG. 15B, the first sacrifice film 47 is pattern formed such that its pitch in the second direction is twice that of the third mask layer 46.

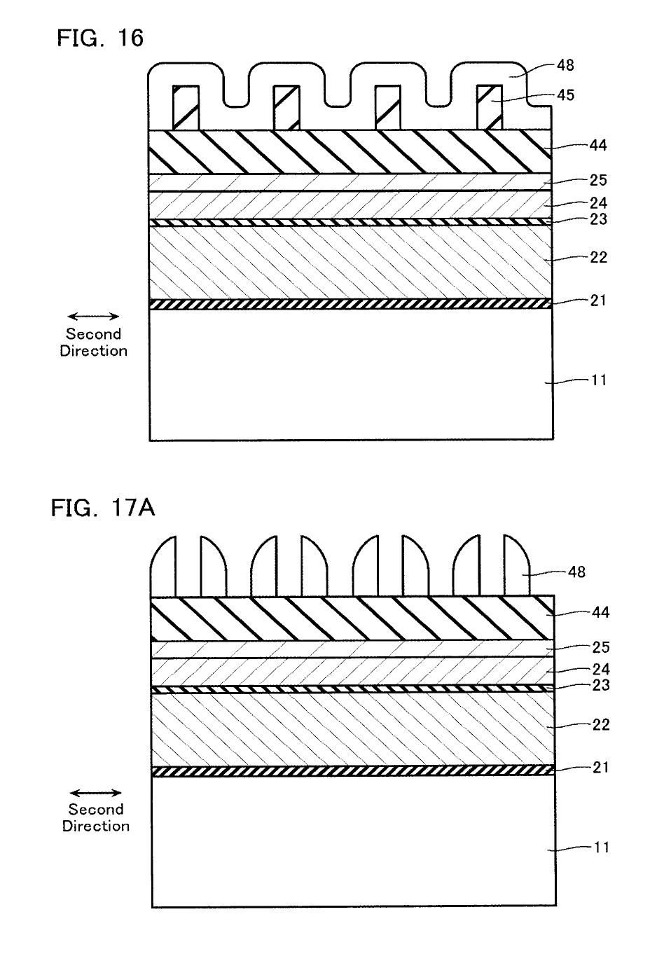

Next, as shown in FIG. 16, etching is performed using the first sacrifice film 47 as a mask, and the second mask layer 45 is pattern formed. Following this, a second sacrifice film 48 is formed on the upper surface and side surfaces of the second mask layer 45 and on an upper surface of the first mask layer 44.

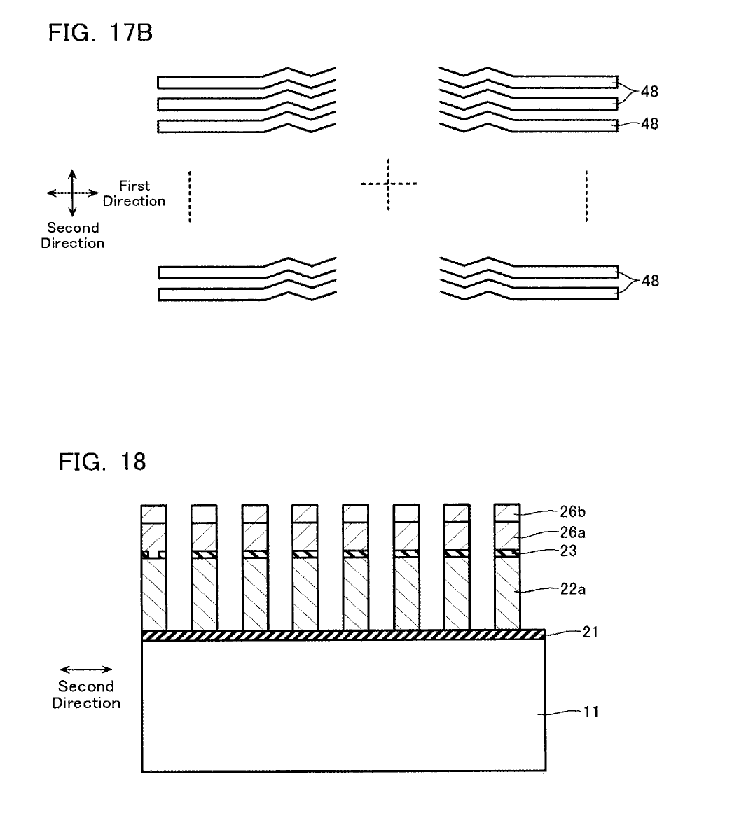

Next, as shown in FIG. 17A, the second sacrifice film 48 is removed leaving a portion formed on the side surfaces of the second mask layer 45, and then, the second mask layer 45 is removed. As a result, as shown in FIG. 17B, the second sacrifice film 48 is pattern formed such that its pitch in the second direction is twice that of the second mask layer 45.

Next, as shown in FIG. 18, etching is performed using the second sacrifice film 48 as a mask, and the first mask layer 44 is pattern formed. Following this, etching is performed using the pattern-formed first mask layer 44 as a mask, and the tungsten silicide film 25, the polysilicon film 24, the second gate insulating film 23, and the polysilicon film 22 undergo patterning. As a result, as shown in FIG. 18, the polysilicon film 22 is formed in a shape of the floating gate electrode 22a of each of the memory cells 2, and the polysilicon film 24 and tungsten silicide film 25 are formed in shapes of the films 26a and 26b forming the control gate electrode 26 of each of the memory cells 2.

Then, formation of the source-drain diffusion layers 14a, 14b, and 14c by ion implantation/thermal diffusion, formation of the inter-layer insulating film 41, formation of the bit line 1, and formation of the bit line contact 6 are performed, whereby a cell array of the NAND type flash memory of the kind shown in FIGS. 2, 3A, 3B, and 4 is obtained.

Now, sometimes, as miniaturization and raising of integration level of the nonvolatile semiconductor memory device proceeds, aspect ratio of the word lines WL rises. In this case, sometimes, as shown in, for example, FIG. 18, width in the second direction of a layer divided in the second direction of the likes of the tungsten silicide film 25 or polysilicon film 24 is narrow, it becomes difficult for posture in the second direction of the layer to be maintained, and the layer ends up collapsing in the second direction.

Accordingly, in the method of manufacturing a nonvolatile semiconductor memory device according to the present embodiment, in a process for dividing a control gate formation layer in the second direction, the control gate formation layer is formed in a shape comprising: the first portion 501 intersecting the second direction at the first angle; and the second portion 502 intersecting the second direction at the second angle different from the first angle. In such a mode, the above-described layer divided in the second direction is formed in a range which is broader than the width in the second direction. Therefore, it is possible to suppress collapse in the dividing direction while achieving miniaturization and raising of integration level of the control gate electrode 26, and it is possible for the nonvolatile semiconductor memory device to be stably manufactured.

Note that as explained with reference to FIGS. 13A, 13B, 13C, and 14 to 18, the present embodiment utilizes a so-called sidewall transfer process in which a sidewall having a pattern formed by lithography is utilized to form a pattern which is finer than this pattern. However, it is also possible to adopt a method different from this. For example, the word lines WL, and so on, may be formed directly by a pattern formed by lithography.

### Second Embodiment

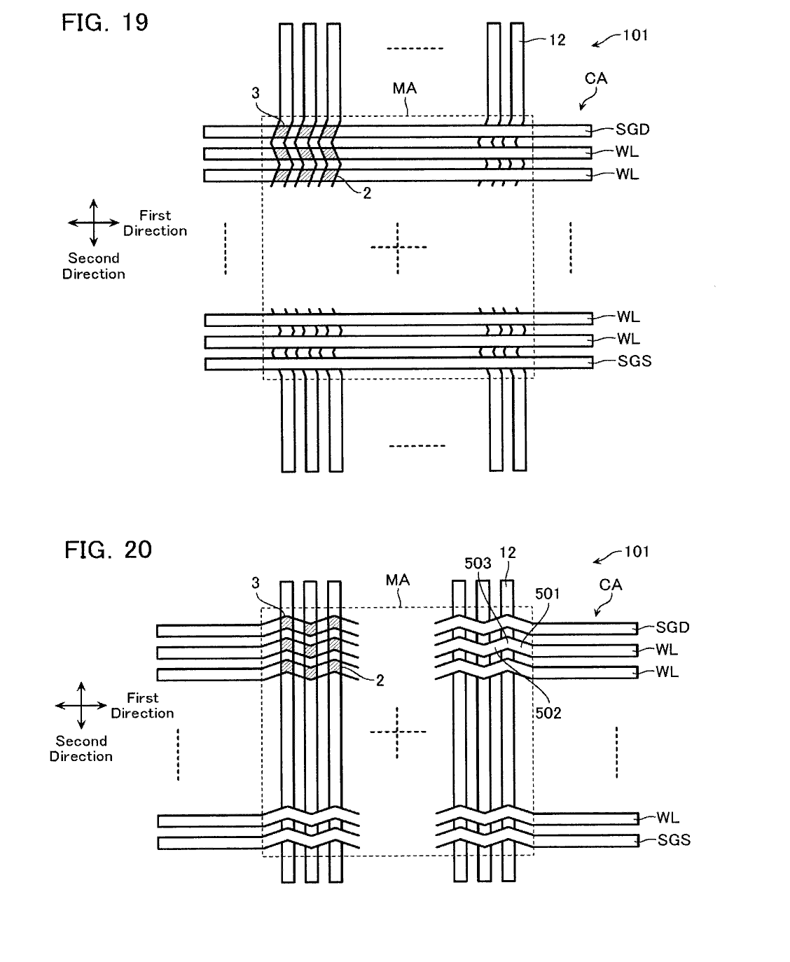

Next, a second embodiment will be described with reference to FIG. 19. FIG. 19 is a schematic plan view of a memory cell array 101 according to the second embodiment.

In the nonvolatile semiconductor memory device according to the first embodiment, part of the word lines WL and the select gate lines SGD and SGS was formed in zigzags. In contrast, as shown in FIG. 19, in a nonvolatile semiconductor memory device according to the present embodiment, part of the semiconductor layer 12 is formed in zigzags. Note that the semiconductor layer 12 is formed substantially linearly in the lead-out wiring line area CA positioned outside of the memory area MA, and extends in the second direction. On the other hand, in the present embodiment, the word lines WL and the select gate lines SGD and SGS are formed substantially linearly and extend in the first direction.

That is, in the present embodiment, as shown in, for example, FIG. 6, by providing a zigzag portion in the semiconductor layer 12, a layer divided in the first direction is formed in a range which is broader than a width in the first direction. This makes it possible to maintain width in the dividing direction and suppress collapse in the dividing direction while achieving miniaturization and raising of integration level of the semiconductor layer 12, and makes it possible for the nonvolatile semiconductor memory device to be stably manufactured.

Note that in other respects, the nonvolatile semiconductor memory device according to the present embodiment is configured similarly to the nonvolatile semiconductor memory device according to the first embodiment.

### Third Embodiment

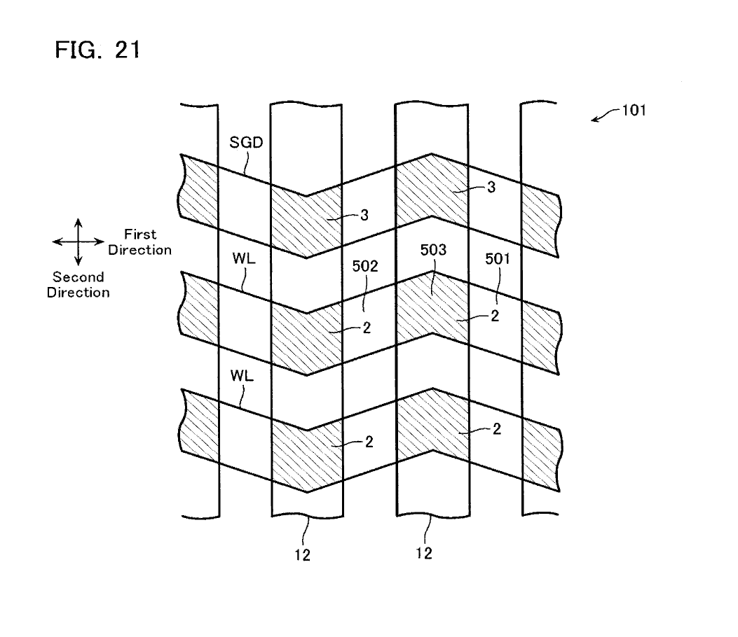

Next, a third embodiment will be described with reference to FIGS. 20 and 21. FIG. 20 is a schematic plan view of a memory cell array 101 according to the third embodiment, and FIG. 21 is an enlarged view of part of FIG. 20.

In the nonvolatile semiconductor memory device according to the first embodiment, the word line WL intersected the semiconductor layer 12 at close to the center of the first portion 501 and the second portion 502, of the zigzag shape, and the memory cell 2 was formed at this intersection. In contrast, as shown in FIGS. 20 and 21, in a nonvolatile semiconductor memory device according to the present embodiment, the word line WL intersects the semiconductor layer 12 at a bend portion 503 between the first portion 501 and the second portion 502, of the zigzag shape, and the memory cell 2 is formed at this intersection. Therefore, as shown in FIGS. 20 and 21, in the present embodiment, positions in the second direction of the memory cells 2 connected to an identical word line WL and adjacent to each other, are different. In other words, in the present embodiment, a position in the second direction of the memory cell 2 (floating gate electrode 22a) formed below an identical word line WL differs periodically along a direction of extension of the word line WL. This makes it possible to increase a distance between fellow memory cells 2 and lower parasitic capacitance while achieving miniaturization and raising of integration level of the word line WL. Note that the distance between fellow memory cells 2 can be maximized between adjacent semiconductor layers 12 and parasitic capacitance between fellow memory cells 2 can be most reduced, when a period with which the memory cells 2 are disposed is misaligned by a half period portion between these semiconductor layers 12.

Note that in other respects, the nonvolatile semiconductor memory device according to the present embodiment is configured similarly to the nonvolatile semiconductor memory device according to the first embodiment. However, similarly to in the second embodiment, for example, it is possible to provide a zigzag portion in the semiconductor layer 12, and furthermore, intersect the semiconductor layer 12 and the word line WL at a bend portion of the semiconductor layer 12. As a result, it is also possible for memory cells 2 connected to an identical semiconductor layer 12 and adjacent to each other to have their positions in the first direction made different. In other words, a position in the first direction of the memory cell 2 (floating gate electrode 22a) formed above an identical semiconductor layer 12 may differ periodically along a direction of extension of the semiconductor layer 12.

### Fourth Embodiment

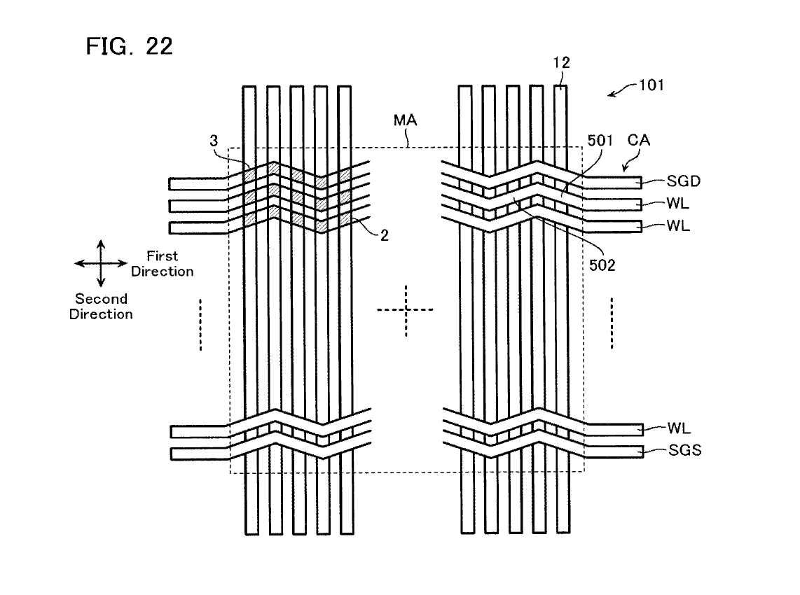

Next, a fourth embodiment will be described with reference to FIG. 22. FIG. 22 is a schematic plan view of a memory cell array 101 according to the fourth embodiment.

In the first embodiment, the word line WL was formed in zigzags with a period which is twice a period with which the semiconductor layers 12 are arranged. In contrast, in the present embodiment, the word line WL is formed in zigzags with a period which is four times a period with which the semiconductor layers 12 are arranged. Therefore, by setting the angles of the first portion 501 and the second portion 502 of the word line WL similarly to in the first through third embodiments, it is possible to further increase the width in the second direction of the word line WL and more suitably prevent collapse of the layer divided in the second direction.

Note that a period of a portion where the word line WL is formed in zigzags may be appropriately changed, and in an extreme case, the word line WL may be formed so as to comprise one each of the first portion 501 and the second portion 502 in the memory area MA, that is, such that the word line WL bends only in one place. Moreover, as shown in FIG. 22, positions in the second direction of the memory cells 2 connected to an identical word line WL and adjacent to each other, are different also in such a mode. Therefore, parasitic capacitance between the memory cells 2 can be lowered.

Note that in other respects, the nonvolatile semiconductor memory device according to the present embodiment is configured similarly to the nonvolatile semiconductor memory device according to the first embodiment. However, similarly to in the second embodiment, for example, it is also possible to provide a zigzag portion in the semiconductor layer 12, and set a period of this zigzag portion to four times a period with which the word lines WL are arranged, or set the period of this zigzag portion to another period.

### Fifth Embodiment

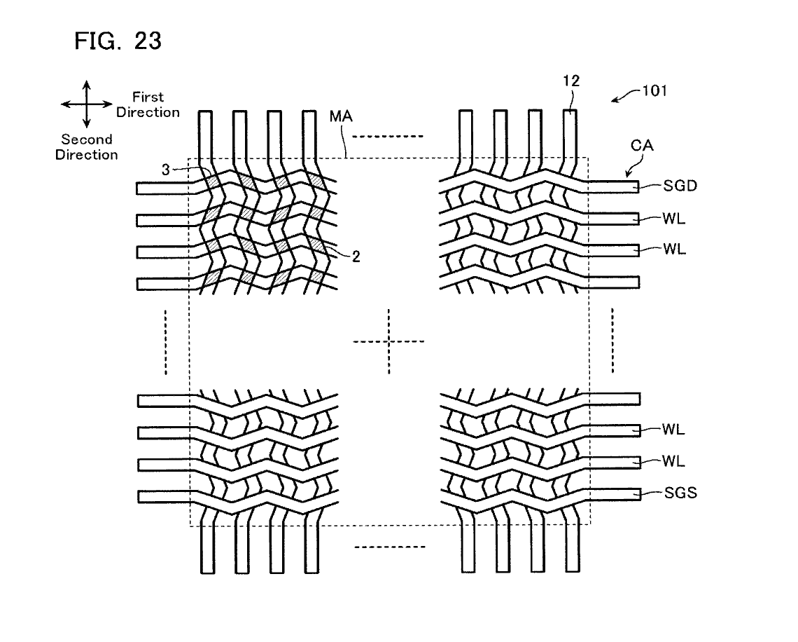

Next, a fifth embodiment will be described with reference to FIG. 23. FIG. 23 is a schematic plan view of a memory cell array 101 according to the fifth embodiment.

In the above-described first through fourth embodiments, only one of the word line WL and the semiconductor layer 12 was formed in zigzags in the memory area MA. In contrast, as shown in FIG. 23, in the fifth embodiment, both the word line WL and the semiconductor layer 12 are formed in zigzags in the memory area MA. Therefore, it is possible to maintain width in the dividing direction and suppress collapse in the dividing direction while achieving miniaturization and raising of integration level for both the word line WL and the semiconductor layer 12, and it is possible for the nonvolatile semiconductor memory device to be stably manufactured.

Note that in other respects, the nonvolatile semiconductor memory device according to the present embodiment is configured similarly to the nonvolatile semiconductor memory devices according to the first through fourth embodiments.

### Sixth Embodiment

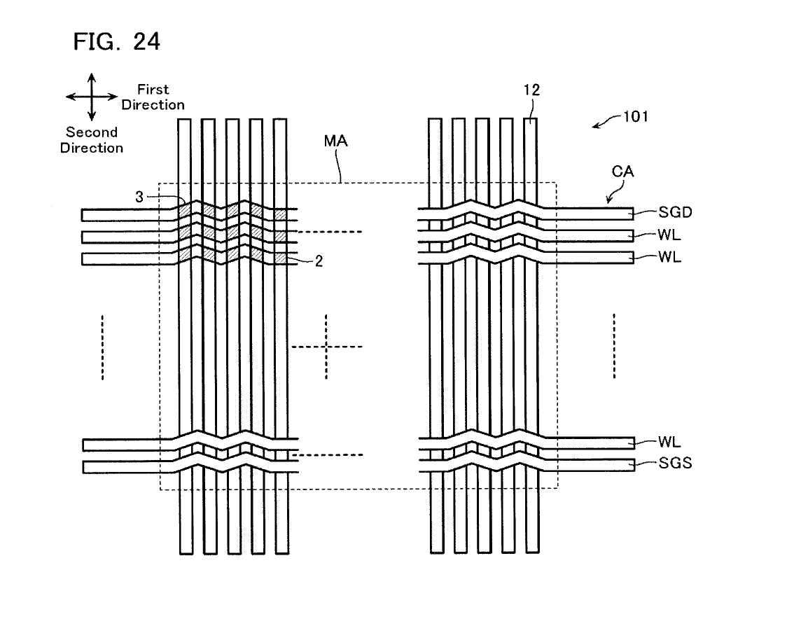

Next, a sixth embodiment will be described with reference to FIG. 24. FIG. 24 is a schematic plan view of a memory cell array 101 according to the sixth embodiment.

In the first embodiment, all of the word line WL was formed in zigzags, in the memory area MA. In contrast, as shown in FIG. 24, in the present embodiment, only part of the word line WL is formed in zigzags and another portion thereof is formed substantially linearly, in the memory area MA.

Note that in other respects, the nonvolatile semiconductor memory device according to the present embodiment is configured similarly to the nonvolatile semiconductor memory device according to the first embodiment. However, it is possible for only part of the semiconductor layer 12 to be formed in zigzags and another portion thereof to be formed substantially linearly, in the memory area MA, for example. Moreover, it is also possible for both of the word line WL and the semiconductor layer 12 to be formed in this way.

### Seventh Embodiment

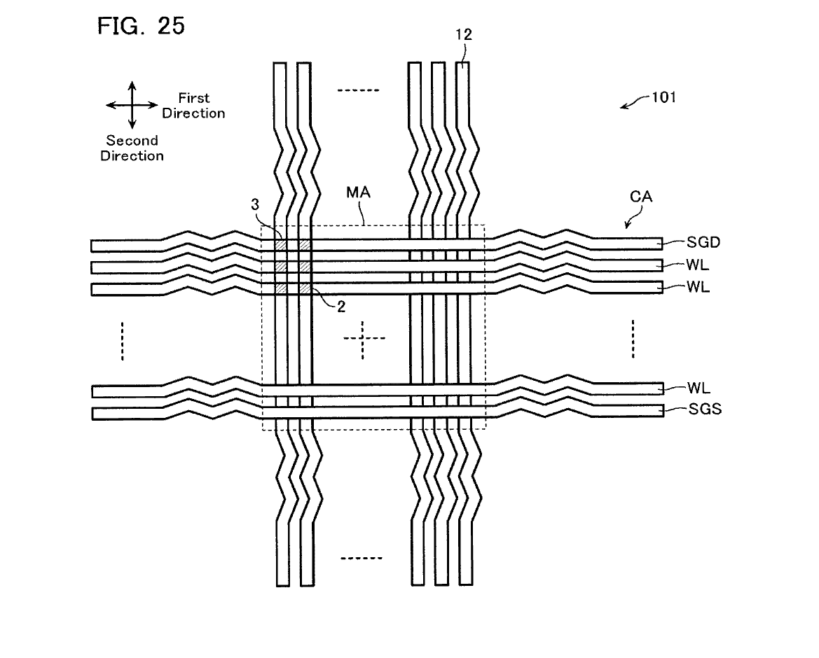

Next, a seventh embodiment will be described with reference to FIG. 25. FIG. 25 is a schematic plan view of a memory cell array 101 according to the seventh embodiment.

In the above-described first through sixth embodiments, at least one of the word line WL and the semiconductor layer 12 was formed in zigzags in the memory area MA and was formed substantially linearly in the lead-out wiring line area CA positioned outside of the memory area MA. In contrast, in the present embodiment, both of the word line WL and the semiconductor layer 12 are formed substantially linearly in the memory area MA, and have part thereof formed in zigzags and a remaining portion thereof formed substantially linearly in the lead-out wiring line area CA.

In the present embodiment, both of the word line WL and the semiconductor layer 12 can be formed substantially linearly in the memory area MA. Therefore, contamination, and so on, can be suitably removed in the likes of an etching process, for example, and manufacturing of the nonvolatile semiconductor memory device can be suitably performed.

Note that in other respects, the nonvolatile semiconductor memory device according to the present embodiment is configured similarly to the nonvolatile semiconductor memory device according to the first embodiment. Note that it is also possible for one of the word line WL and the semiconductor layer 12 to be formed substantially linearly, for example.

### Eighth Embodiment

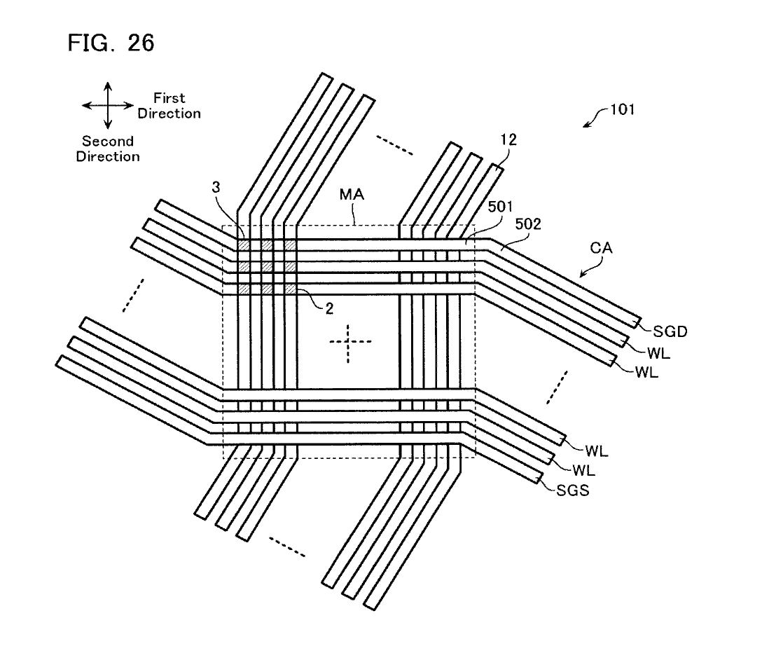

Next, an eighth embodiment will be described with reference to FIG. 26. FIG. 26 is a schematic plan view of a memory cell array 101 according to the eighth embodiment.

In the first through seventh embodiments, at least one of the word line WL and the semiconductor layer 12 had part thereof formed in zigzags. In contrast, as shown in FIG. 26, in the present embodiment, the word line WL and the semiconductor layer 12 bend differently within the memory area MA and in the lead-out wiring line area CA. In such a mode, for example, a portion within the memory area MA of the word line WL is the first portion 501, and a portion in the lead-out wiring line area CA of the word line WL is the second portion 502. Such a mode also makes it possible to maintain width in the dividing direction and suppress collapse in the dividing direction while achieving miniaturization and raising of integration level of the word line WL and the semiconductor layer 12, and makes it possible for the nonvolatile semiconductor memory device to be stably manufactured.

Moreover, as shown in FIG. 26, such a mode also makes it possible for both of the word line WL and the semiconductor layer 12 to be formed substantially linearly in the memory area MA. Therefore, contamination, and so on, can be suitably removed in the likes of an etching process, for example, and manufacturing of the nonvolatile semiconductor memory device can be suitably performed.

### Other Embodiments

Each of the above-described embodiments described, as an example, a NAND type flash memory and a method of manufacturing the same. However, the method according to each of the above-described embodiments can be applied to any semiconductor memory device that comprises, for example: a plurality of first lines; a plurality of second lines intersecting these first lines; and a memory cell formed at each of intersections of these first lines and second lines. It is also possible for a semiconductor memory device such as a DRAM (Dynamic Random Access Memory), a SRAM (Static Random Access Memory), a ReRAM (Resistive Random Access Memory), and a NOR type flash memory, for example, to be applied as such a semiconductor memory device.

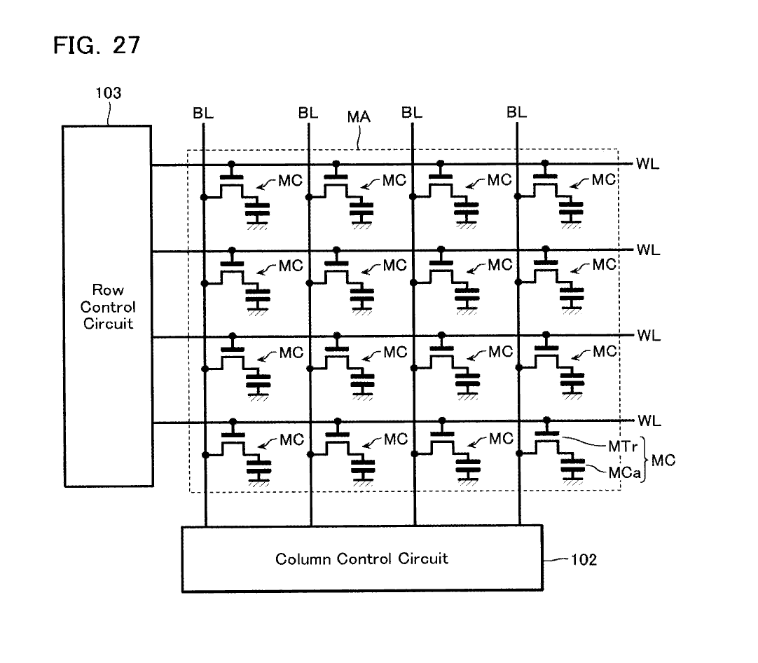

FIG. 27 is a circuit diagram for explaining an example of another embodiment. FIG. 27 shows a circuit diagram of a DRAM. The semiconductor memory device shown in FIG. 27 comprises: a plurality of bit lines BL arranged in a first direction; a plurality of word lines WL arranged in a second direction intersecting the first direction; and memory cells MC positioned at each of intersections of the plurality of bit lines BL and the plurality of word lines WL. The memory cell MC comprises a memory transistor MTr and a memory capacitor MCa connected in series between the bit line BL and a ground terminal. Note that a gate terminal of the memory transistor MTr is connected to the word line WL.

In such a semiconductor memory device, at least one of the bit line BL and the word line WL comprises: a first portion intersecting a certain direction at a first angle; and a second portion intersecting the certain direction at a second angle different from the first angle. Moreover, at least one of the bit line BL and the word line WL may be formed in zigzags. In addition, a position of the memory cell MC may differ periodically along a direction of extension of the bit line BL or the word line WL. Furthermore, at least one of the bit line BL and the word line WL may be formed in zigzags in the memory area MA, or may be formed in zigzags in the lead-out wiring line area CA positioned outside of the memory area MA.

[Others]

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a semiconductor layer provided on a substrate and extending in a certain direction;
a first gate insulating film formed on the semiconductor layer;
a floating gate electrode formed along the semiconductor layer on the first gate insulating film;
a second gate insulating film formed on an upper surface of the floating gate electrode; and
a control gate electrode facing the upper surface of the floating gate electrode via the second gate insulating film,
the control gate electrode comprising: a first portion intersecting the certain direction at a first angle; and a second portion intersecting the certain direction at a second angle different from the first angle.

2. The semiconductor memory device according to claim 1, wherein
at least part of the control gate electrode is formed in zigzags.

3. The semiconductor memory device according to claim 2, further comprising:
a plurality of the semiconductor layers arranged in a first direction;
a plurality of the floating gate electrodes formed along the semiconductor layer on the first gate insulating film; and
a plurality of the control gate electrodes arranged in a second direction intersecting the first direction, and facing the upper surface of the plurality of floating gate electrodes formed on different semiconductor layers, via the second gate insulating film.

4. The semiconductor memory device according to claim 3, wherein
positions in the second direction of the floating gate electrode formed below an identical control gate electrode differ periodically along a direction of extension of the control gate electrode.

5. The semiconductor memory device according to claim 3, wherein
the control gate electrode is formed in zigzags with a period which is twice a period with which the semiconductor layers are arranged.

6. The semiconductor memory device according to claim 3, wherein
the control gate electrode is formed in zigzags with a period which is different from a period which is twice a period with which the semiconductor layers are arranged.

7. The semiconductor memory device according to claim 3, wherein
the plurality of semiconductor layers and the plurality of control gate electrodes intersect in a memory area and are led out from a lead-out wiring line area positioned outside of the memory area, and
at least part of the control gate electrode is formed in zigzags in the memory area.

8. The semiconductor memory device according to claim 3, wherein
the plurality of semiconductor layers and the plurality of control gate electrodes intersect in a memory area and are led out from a lead-out wiring line area positioned outside of the memory area, and
at least part of the control gate electrode is formed in zigzags in the lead-out wiring line area.

9. A semiconductor memory device, comprising:
a semiconductor layer provided on a substrate;
a first gate insulating film formed on the semiconductor layer;
a floating gate electrode formed along the semiconductor layer on the first gate insulating film;
a second gate insulating film formed on an upper surface of the floating gate electrode; and
a control gate electrode facing the upper surface of the floating gate electrode via the second gate insulating film and extending in a certain direction,
the semiconductor layer comprising: a first portion intersecting the certain direction at a first angle; and a second portion intersecting the certain direction at a second angle different from the first angle.

10. The semiconductor memory device according to claim 9, wherein
at least part of the semiconductor layer is formed in zigzags.

11. The semiconductor memory device according to claim 10, further comprising:
a plurality of the semiconductor layers arranged in a first direction;
a plurality of the floating gate electrodes formed along the semiconductor layer on the first gate insulating film; and
a plurality of the control gate electrodes arranged in a second direction intersecting the first direction, and facing the upper surface of the plurality of floating gate electrodes formed on different semiconductor layers, via the second gate insulating film.

12. The semiconductor memory device according to claim 11, wherein
positions in the first direction of the floating gate electrode formed above an identical semiconductor layer differ periodically along a direction of extension of the semiconductor layer.

13. The semiconductor memory device according to claim 11, wherein
the semiconductor layer is formed in zigzags with a period which is twice a period with which the control gate electrodes are arranged.

14. The semiconductor memory device according to claim 11, wherein
the semiconductor layer is formed in zigzags with a period which is different from a period which is twice a period with which the control gate electrodes are arranged.

15. The semiconductor memory device according to claim 11, wherein
the plurality of semiconductor layers and the plurality of control gate electrodes intersect in a memory area and are led out from a lead-out wiring line area positioned outside of the memory area, and
at least part of the semiconductor layer is formed in zigzags in the memory area.

16. The semiconductor memory device according to claim 11, wherein
the plurality of semiconductor layers and the plurality of control gate electrodes intersect in a memory area and are led out from a lead-out wiring line area positioned outside of the memory area, and
at least part of the semiconductor layer is formed in zigzags in the lead-out wiring line area.

17. A semiconductor memory device, comprising:
first lines arranged in a first direction;
second lines arranged in a second direction intersecting the first direction; and
a memory cell positioned at an intersection of the first line and the second line;
the first line comprising: a first portion intersecting the second direction at a first angle; and a second portion intersecting the second direction at a second angle different from the first angle.

18. The semiconductor memory device according to claim 17, wherein
at least part of the first line is formed in zigzags.

19. The semiconductor memory device according to claim 18, wherein
the first lines and the second lines intersect in a memory area and are led out from a lead-out wiring line area positioned outside of the memory area, and
at least part of the first line is formed in zigzags in the memory area.

20. The semiconductor memory device according to claim 18, wherein
the first lines and the second lines intersect in a memory area and are led out from a lead-out wiring line area positioned outside of the memory area, and
at least part of the first line is formed in zigzags in the lead-out wiring line area.
